(19) United States
(12) Patent Application Publication
(10) Pub. No.: US 2011/0056560 A1
(43) Pub. Date: Mar. 10, 2011

(54) SOLAR CELL MODULE AND MANUFACTURING METHOD THEREOF

(75) Inventors: Yuji Kitamura, Gifu-shi (JP); Kazuya Murata, Anpachi-gun (JP); Hirotaka Katayama, Gifu-shi (JP)

(73) Assignee: SANYO ELECTRIC CO., LTD., Moriguchi-shi (JP)

(21) Appl. No.: 12/875,542

(22) Filed: Sep. 3, 2010

(30) Foreign Application Priority Data
Sep. 7, 2009 (JP) 2009-205618

(51) Int. Cl. H01L 31/04; H01L 31/18

(52) U.S. Cl. 136/261; 438/97; 257/E31.04

(57) ABSTRACT

Reduction in characteristic due to non-uniformity of crystallinity of a microcrystalline silicon film in a surface of a solar cell module is inhibited. A solar cell module is provided having an i-type layer of a microcrystalline silicon film as a photovoltaic layer in a photovoltaic unit (14), the i-type layer has a first region (30) and a second region (32) having a lower crystallization percentage than the first region (30) in the surface, and a tab electrode (22) to a terminal box (24) of the solar cell module (100) is formed overlapping the second region (32).

### CROSS-REFERENCE TO RELATED APPLICATION

The entire disclosure of Japanese Patent Application No. 2009-205618 filed on Sep. 7, 2009, including specification, claims,drawings,andabstract,isincorporatedhereinbyreference in its entirety.

### BACKGROUND

1. Technical Field

The present invention relates to a solar cell module and a manufacturing method of a solar cell module.

2. Background Art

A solar cell module is formed by sequentially layering a first electrode, one or more semiconductor thin film photovoltaic units, and a second electrode over a substrate having an insulating surface. Each photovoltaic unit is formed by layering a p-type layer, an i-type layer which forms a photoelectric conversion layer, and an n-type layer from the side of incidence of light.

As the solar cell module, there exists a single-type solar cell module having a single photovoltaic unit of a microcrystalline silicon film, and a tandem-type solar cell module in which a photovoltaic unit of an amorphous silicon film and a photovoltaic unit of a microcrystalline silicon film are layered.

Normally, in order to improve a photoelectric conversion characteristic in the solar cell module, it is desirable that the crystallinity in a surface of the microcrystalline silicon film be uniform. However, in reality, because of the performances of the film forming devices for the microcrystalline silicon film and a further increase in the area of the solar cell module, it is difficult to achieve a sufficiently uniform crystallinity in the surface of the microcrystalline silicon film. As a result, in the solar cell module having the photovoltaic unit of the microcrystalline silicon, the crystallization percentage in a peripheral region becomes lower than that in the center region in the surface, an amount of generation of the carriers becomes lower in the peripheral region than the center region during power generation, and the photoelectric conversion efficiency becomes non-uniform in the surface. Because of this, there may be cases where the characteristic is reduced for the solar cell module as a whole.

### SUMMARY

According to one aspect of the present invention, there is provided a solar cell module comprising a microcrystalline silicon film as a photovoltaic layer, wherein the microcrystalline silicon film of the photovoltaic layer comprises a first region and a second region having a lower crystallization percentage than the first region in a surface of the solar cell module, and a tab electrode to a terminal box of the solar cell module is placed in a manner to overlap the second region.

According to another aspect of the present invention, there is provided a method of manufacturing a solar cell module having a microcrystalline silicon film as a photovoltaic layer, the method comprising forming a microcrystalline silicon film comprising a first region and a second region having a lower crystallization percentage than the first region in a surface of the solar cell module, and forming a tab electrode to a terminal box of the solar cell module in a manner to overlap the second region.

### BRIEF DESCRIPTION OF THE DRAWINGS

Preferred embodiments of the present invention will be described in detail based on the following drawings, wherein:

FIG. 1 is a plan view showing a structure of a tandem-type solar cell module in a preferred embodiment of the present invention;

FIG. 2 is a cross sectional diagram showing a structure of a tandem-type solar cell module in a preferred embodiment of the present invention;

FIG. 3 is a cross sectional diagram showing a structure of a tandem-type solar cell module in a preferred embodiment of the present invention;

FIG. 4 is a diagram showing an example of a structural distribution in a surface of an i-type layer of a μc-Si unit in a preferred embodiment of the present invention;

FIG. 5 is a diagram showing a crystallization percentage in a surface of an i-type layer of a μc-Si unit in a preferred embodiment of the present invention; and

FIG. 6 is a diagram showing a lifetime of a carrier in a surface of an i-type layer of a μc-Si unit in a preferred embodiment of the present invention.

### DESCRIPTION OF EMBODIMENTS

### First Preferred Embodiment

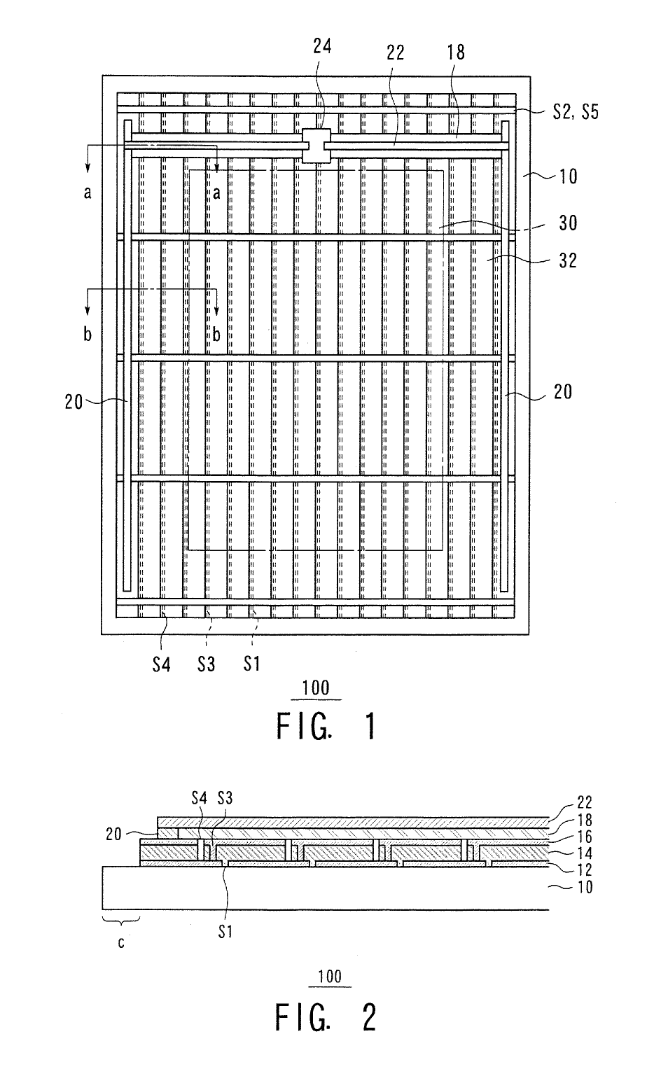

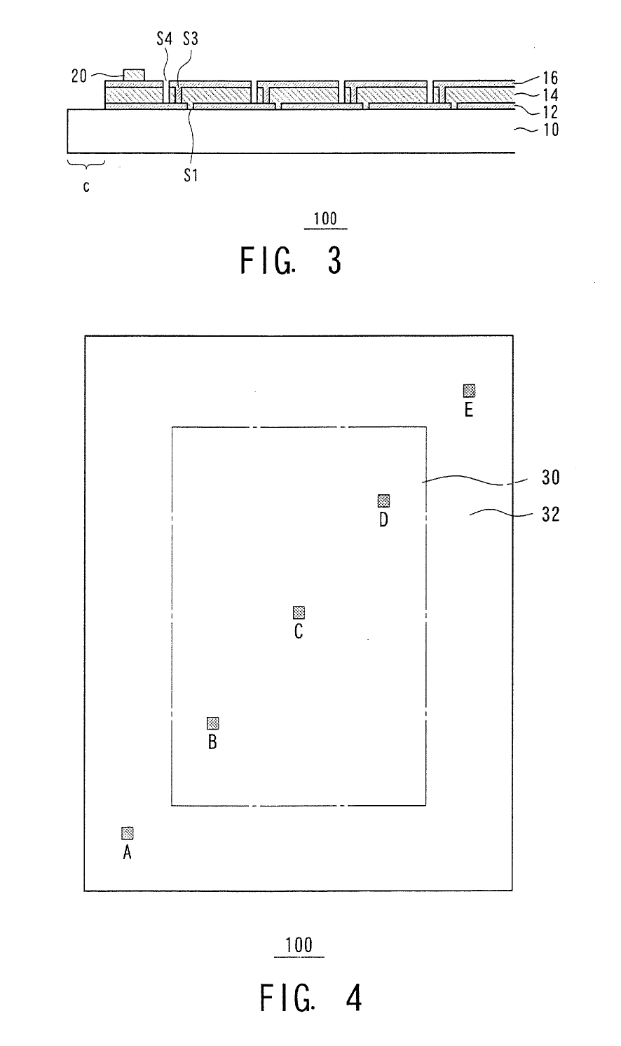

FIGS. 1-3 are diagrams showing a structure of a tandem-type solar cell module 100 in a preferred embodiment of the present invention. FIG. 1 is a plan view viewed from a side opposite to the side of incidence of light, FIG. 2 is a cross sectional diagram along a line a-a of FIG. 1, and FIG. 3 is a cross sectional diagram along a line b-b of FIG. 1. In the actual tandem-type solar cell module 100, an insulating tape covering a tab electrode, EVA which forms a protection member, and a back sheet are formed, but these structures are not shown in order to more clearly show the structure.

The tandem-type solar cell module 100 comprises, with a transparent insulating substrate 10 as a light incidence side, a transparent conductive film 12, a photovoltaic unit 14, a backside electrode 16, an insulating tape 18, tab electrodes 20 and 22, and a terminal box 24, layered from the light incidence side.

A structure and a manufacturing method of the tandem-type solar cell module 100 in the present embodiment will now be described.

For the transparent insulating substrate 10, a material having a light transmittance at least in a visible light wavelength region may be used, such as, for example, a glass substrate and a plastic substrate. The transparent conductive film 12 is formed over the transparent insulating substrate 10. For the transparent conductive film 12, it is preferable to use at least one or a combination of a plurality of transparent conductive oxides (TCO) in which tin (Sn), antimony (Sb), fluorine (F), aluminum (Al), or the like is contained in tin oxide (SnO₂), zinc oxide (ZnO), indium tin oxide (ITO), or the like. In particular, zinc oxide (ZnO) is preferable because of its high light transmittance, low resistivity, and high plasma endurance characteristic. The transparent conductive film 12 maybe formed through, for example, sputtering. A thickness of the transparent conductive film 12 is preferably set in a range of greater than or equal to 500 nm and less than or equal to 5000 nm. In addition, unevenness having a light confinement effect is preferably formed on the surface of the transparent conductive film 12.

As shown in FIGS. 2 and 3, when the tandem-type solar cell module 100 is formed to have a structure in which a plurality of cells are connected in series, a slit S1 in which a surface of the transparent insulating substrate 10 is exposed is formed in the transparent conductive film 12, and the transparent conductive film 12 is patterned to a strip shape. In addition, as shown in the plan view of FIG. 1, a slit S2 in which the surface of the transparent insulating substrate 10 is exposed may be formed in a direction crossing a direction of extension of the slit S1, to form a structure in which a plurality of groups of photovoltaic cells connected in series are arranged in parallel to each other.

For example, the slits S1 and S2 may be formed using a YAG laser having a wavelength of 1064 nm, an energy density of 13 J/cm², and a pulse frequency of 3 kHz.

The photovoltaic unit 14 is formed over the transparent conductive film 12. In the tandem-type solar cell module 100 in the present embodiment, the photovoltaic unit 14 has a structure in which an amorphous silicon photovoltaic unit (a-Si unit) functioning as a top cell and having a wide band gap, an intermediate layer, and a microcrystalline silicon photovoltaic unit (μc-Si unit) functioning as a bottom cell and having a narrower band gap than the a-Si unit are sequentially layered. For example, the photovoltaic unit 14 may be formed through formation conditions as shown in TABLE 1. In TABLE 1, diborane (B₂H₆) and phosphine (PH₃) are gases diluted to 1% based on hydrogen.

TABLE 1

| | | SUBSTRATE | GAS FLOW | REACTION | | |
|---|---|---|---|---|---|---|
| | | TEMPERATURE | RATE | PRESSURE | RF POWER | THICKNESS |
| | LAYER | (° C.) | (sccm) | (Pa) | (W) | (nm) |
| a-Si unit | p | 180 | SiH₄: 100 | 100 | 30 | 10 |
| | LAYER | | CH₄: 10 | | (11 mW/cm²) | |
| | | | H₂: 1000 | | | |
| | | | B₂H₆: 50 | | | |
| | i | 180 | SiH₄: 300 | 100 | 30 | 300 |
| | LAYER | | H₂: 1000 | | (11 mW/cm²) | |
| | n | 180 | SiH₄: 10 | 200 | 300 | 20 |
| | LAYER | | H₂: 2000 | | (110 mW/cm²) | |
| | | | PH₃: 5 | | | |
| μ c-Si | p | 180 | SiH₄: 10 | 200 | 300 | 10 |
| unit | LAYER | | H₂: 2000 | | (110 mW/cm²) | |
| | | | B₂H₆: 5 | | | |
| | i | 180 | SiH₄: 50 | 600 | 600 | 2000 |
| | LAYER | | H₂: 3000 | | (220 mW/cm²) | |
| | n | 180 | SiH₄: 10 | 200 | 300 | 20 |
| | LAYER | | H₂: 2000 | | (110 mW/cm²) | |
| | | | PH₃: 5 | | | |

First, the a-Si unit is formed by sequentially layering silicon-based thin films of a p-type layer, an i-type layer, and an n-type layer over the transparent conductive film 12. The a-Si unit may be formed by plasma chemical vapor deposition (plasma CVD) in which mixture gas in which silicon-containing gas such as silane (SiH₄), disilane (Si₂H₆), and dichlorsilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) are mixed is made into plasma, and a film is formed.

For the plasma CVD, for example, an RF plasma CVD of 13.56 MHz maybepreferablyapplied. TheRFplasmaCVDmaybeofaparallel plate type. Alternatively, a structure maybe employed in which a gas shower hole for supplying the mixture gas of materials is formed on a side, of the electrodes of the parallel plate type, on which the transparent insulating substrate 10 is not placed. An input power density of the plasma is preferably set to greater than or equal to 5 mW/cm² and less than or equal to 100 mW/cm².

The p-type layer of the a-Si unit has a single layer structure or a layered structure of an amorphous silicon layer, a microcrystalline silicon thin film, and a microcrystalline silicon carbide thin film, doped with a p-type dopant (such as boron) and having a thickness of greater than or equal to 5 nm and less than or equal to 50 nm. A film characteristic of the p-type layer may be changed by adjusting mixture ratios of the silicon-containing gas, p-type dopant-containing gas, and dilution gas, pressure, and plasma generating high-frequency power. The i-type layer of the a-Si unit is an amorphous silicon film formed over the p-type layer, not doped with any dopant, and having a thickness of greater than or equal to 50 nm and less than or equal to 500 nm. A film characteristic of the i-type layer may be changed by adjusting the mixture ratios of the silicon-containing gas and the dilution gas, pressure, and plasma generating high-frequency power. The i-type layer forms a photoelectric conversion layer of the a-Si unit. The n-type layer of the a-Si unit is an n-type microcrystalline silicon layer (n-type μc-Si:H) formed over the i-type layer, doped with an n-type dopant (such as phosphorus), and having a thickness of greater than or equal to 10 nm and less than or equal to 100 nm. A film characteristic of the n-type layer may be change by adjusting the mixture ratios of the silicon-containing gas, the carbon-containing gas, the n-type dopant-containing gas, and the dilution gas, pressure, and plasma generating high-frequency power.

The intermediate layer is formed over the a-Si unit. For the intermediate layer, a transparent conductive oxide (TCO) such as zinc oxide (ZnO), and silicon oxide (SiOx) is preferably used. In particular, it is preferable to use zinc oxide (ZnO) and silicon oxide (SiOx) to which magnesium is contained. The intermediate layer may be formed, for example, through sputtering. A thickness of the intermediate layer is preferably set in a range of greater than or equal to 10 nm and less than or equal to 200 nm. Alternatively, the intermediate layer may be omitted.

The μc-Si unit in which a p-type layer, an i-type layer, and an n-type layer are sequentially layered is formed over the intermediate layer. The μc-Si unit may be formed through plasma CVD in which mixture gas of silicon-containing gas such as silane (SiH₄), disilane (Si₂H₆), and dichlorsilane (SiH₂Cl₂), carbon-containing gas such as methane (CH₄), p-type dopant-containing gas such as diborane (B₂H₆), n-type dopant containing gas such as phosphine (PH₃), and dilution gas such as hydrogen (H₂) is made into plasma and a film is formed.

For the plasma CVD, similar to the a-Si unit, for example, an RF plasma CVD of 13.56 MHz may be preferably applied. The RF plasma CVD may be of the parallel plate type. Alternatively, a structure may be employed in which a gas shower hole for supplying mixture gas of the materials is formed on a side, of the electrodes of the parallel plate type, on which the transparent insulating substrate 10 is not placed. An input power density of plasma is preferably greater than or equal to 5 mW/cm² and less than or equal to 1500 mW/cm².

The p-type layer of the μc-Si unit is a microcrystalline silicon layer (μc-Si:H) having a thickness of greater than or equal to 5 nm and less than or equal to 50 nm, and doped with a p-type dopant (such as boron). A film characteristic of the p-type layer may be changed by adjusting the mixture ratios of the silicon-containing gas, the p-type dopant-containing gas, and the dilution gas, pressure, and plasma generating high-frequency power.

The i-type layer of the μc-Si unit is a microcrystalline silicon layer (μc-Si:H) formed over the p-type layer, having a thickness of greater than or equal to 500 nm and less than or equal to 5000 nm, and not doped with any dopant. A film characteristic of the i-type layer may be changed by adjusting the mixture ratios of the silicon-containing gas and the dilution gas, pressure, and plasma generating high-frequency power.

The i-type layer of the μc-Si unit is formed in a film formation chamber having a substrate heater, a substrate carrier, and a plasma electrode built into the chamber. The film formation chamber is vacuumed by a vacuum pump. The substrate heater is placed such that a heating surface opposes the plasma electrode. The transparent insulating substrate 10 placed on the substrate carrier is transported between the plasma electrode and the substrate heater in an orientation to face the plasma electrode. The plasma electrode is electrically connected to a plasma power supply through a matching box provided outside of the film formation chamber. In such a structure, while the material gas is supplied at a flow rate and a pressure appropriate to the film formation condition, power is input from the plasma power supply to the plasma electrode, so that plasma of the material gas is generated in the gap between the plasma electrode and the transparent insulating substrate 10 and a film is formed over the surface of the transparent insulating substrate 10.

The i-type layer of the μc-Si unit has, in the surface of the incidence of light of the tandem-type solar cell module 100, a first region 30 and a second region 32 having different crystallinity from each other. For example, in many cases, as shown in FIG. 4, a center region in the surface of the incidence of light of the tandem-type solar cell module 100 is the first region 30 having a high crystallinity (a region surrounded by a dot-and-chain line in FIG. 4), and a peripheral region is the second region 32 having a relatively lower crystallinity than the first region 30 (a region surrounded by a solid line and a dot-and-chain line in FIG. 4).

The crystallinity is measured using Raman spectroscopy after a microcrystalline silicon film is formed to a thickness of 600 nm over a glass substrate under the same film formation conditions as the conditions when the i-type layer (i-type layer of the μc-Si unit) of the tandem-type solar cell module 100 is formed. More specifically, light is irradiated to the respective regions in the surface of the microcrystalline silicon film formed over the glass substrate, and a crystallization percentage X (%) is calculated using the following equation (1) based on a peak intensity I₅₂₀ around 520 cm ⁻¹ derived from crystalline silicon and a peak intensity I₄₈₀ around 480 cm⁻¹ derived from amorphous silicon in the Raman scattering spectrum.

[Equation 1]

Crystallization Percentage×(%)=I₅₂₀/(I₅₂₀+I₄₈₀) (1)

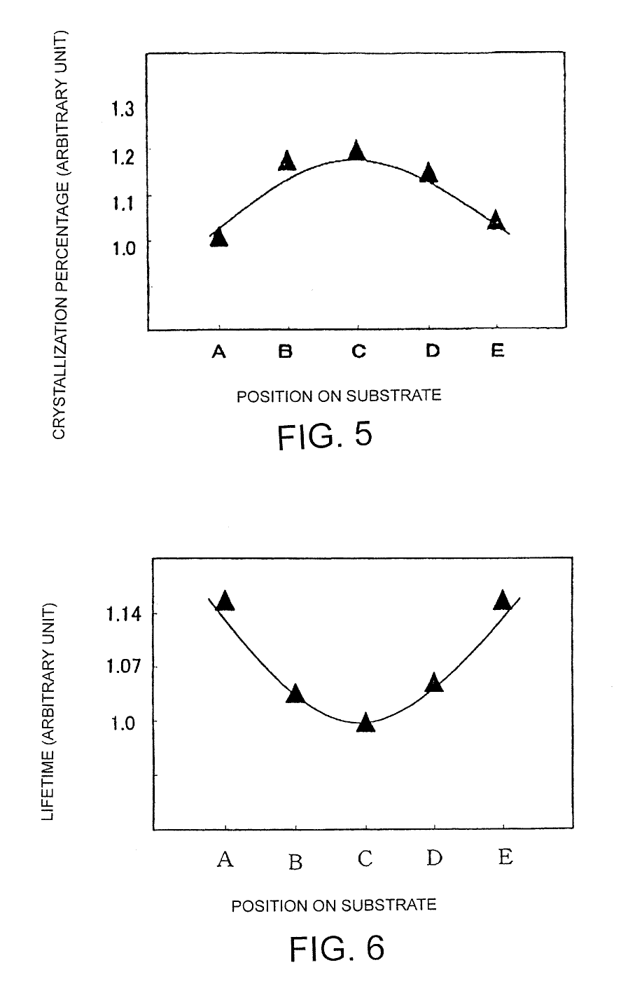

FIG. 5 shows an example measurement of a distribution of the crystallization percentage in the surface of the i-type layer of the μc-Si unit of the tandem-type solar cell module 100 formed in the present embodiment. The crystallization percentage is measured by a Raman spectroscopy after a microcrystalline silicon film is formed to a thickness of 600 nm over a glass substrate under the same film formation conditions as the conditions for forming the i-type layer of the tandem-type solar cell module 100. The measurement result of FIG. 5 shows crystallization percentages in regions A-E of the tandem-type solar cell module 100 shown in FIG. 4. As shown in FIG. 5, when the crystallization percentage in the second region 32 at the periphery of the surface (regions A and E) is 1, a crystallization percentage of the first region 30 at the center of the surface (regions B, C, and D) is greater than or equal to 1.1, and the maximum crystallization percentage in these regions is approximately 1.2.

The n-type layer of the μc-Si unit is formed by layering microcrystalline silicon layers (n-type μc-Si:H) having a thickness of greater than or equal to 5 nm and less than or equal to 50 nm and doped with an n-type dopant (such as phosphorus). A film characteristic of the n-type layer may be changed by adjusting the mixture ratios of the silicon-containing gas, the carbon-containing gas, the n-type dopant-containing gas, and the dilution gas, pressure, and plasma generating high-frequency power.

When a plurality of photovoltaic cells are connected in series, the photovoltaic unit 14 is patterned to a strip shape. A YAG laser is irradiated at a position aside from the patterning position of the slit S1 for separating the transparent conductive film 12 by approximately 50 μm in parallel with the slit S1, to form a slit S3 and pattern the photovoltaic unit 14 in the strip shape. For the YAG laser, for example, a YAG laser having an energy density of 0.7 J/cm² and a pulse frequency of 3 kHz is preferably used.

The backside electrode 16 is formed over the μc-Si unit. The backside electrode 16 is preferably formed by layering a first backside electrode and a second backside electrode. As the first backside electrode, a transparent conductive oxide (TCO) such as tin oxide (SnO₂), zinc oxide (ZnO), and indium tin oxide (ITO) is used. In addition, for the second backside electrode, a metal such as silver (Ag) and aluminum (Al) may be used. The TCO may be formed, for example, through sputtering. The first backside electrode and the second backside electrode are preferably formed to a total thickness of approximately 1000 nm. In addition, it is also preferable to provide unevenness on at least one of the first backside electrode and the second backside electrode for improving the light confinement effect.

When a plurality of cells are connected in series, the backside electrode 16 and the photovoltaic unit 14 are patterned into a strip shape. A YAG laser is irradiated at a position aside from the patterning position of the slit S3 for separating the photovoltaic unit 14 by approximately 50 μm in parallel to the slits S1 and S3, to form a slit S4 and pattern the backside electrode 16 and the photovoltaic unit 14 in a strip shape. For the YAG laser, a YAG laser having an energy density of 0.7 J/cm² and a pulse frequency of 4 kHz is preferably used.

In addition, as shown in FIG. 1, the YAG laser is irradiated in a manner to overlap the slit S2 to form a slit S5, the backside electrode 16 and the photovoltaic unit 14 are removed, and the photovoltaic cell is separated in parallel. A width of the slit S5 is preferably narrower than a width of the slit S2. In addition, the slit S5 can be formed under the same conditions as the slit S4.

Alternatively, a configuration may be employed in which the transparent conductive film 12, the photovoltaic unit 14, and the backside electrode 16 are removed, to expose the surface of the transparent insulating substrate 10 at a peripheral portion c of the solar cell module 100. With this configuration, when a supporting frame or the like is mounted on the solar cell module 100, electrical insulation from the supporting frame can be more reliably achieved.

Because the slits S2 and S5 are formed, a structure is obtained in which a plurality of groups of a plurality of photovoltaic cells connected in series are arranged in parallel to each other. The tab electrode 20 is provided to electrically connect in parallel the groups of photovoltaic cells arranged in parallel to each other. The tab electrode 20 is formed in a direction parallel to the slit S4. The tab electrode 20 may be formed with a material including a conductive metal such as copper (Cu), silver (Ag), and aluminum (Al). For example, a structure is preferably employed in which a surface of a core line made of copper (Cu) is covered (coated) by a solder.

The tab electrode 20 is preferably formed over the backside electrode 16 of an end cell of the plurality of photovoltaic cells connected in series, and electrically connected to the backside electrode 16. In the tandem-type solar cell module 100 of the present embodiment, the tab electrodes 20 are provided at the cells at both ends of the photovoltaic cells connected in series, for electrical connection of the groups of photovoltaic cells.

The tab electrode 22 is provided to electrically connect the tab electrode 20 to the terminal box 24. The tab electrode 22 is formed in parallel to the slits S2 and S5 and from the tab electrode 20 to the terminal box 24. The insulating tape 18 is formed below the region where the tab electrode 22 is formed so that the plurality of photovoltaic cells connected in series are not connected in parallel by the tab electrode 22. The tab electrode 22 is provided over the insulating tape 18.

In addition, the tab electrode 20 and the tab electrode 22 may be covered with an insulating tape. Moreover, the surface of the tandem-type solar cell module 100 maybe covered andprotected by EVA which forms a protection member and a back sheet. With such configurations, intrusion of moisture or the like to the photoelectric conversion layer of the tandem-type solar cell module 100 can be prevented.

As shown in FIG. 1, the tab electrode 22 is placed to overlap the second region 32 of the tandem-type solar cell module 100. In other words, the tab electrode 22 is formed to overlap not the first region 30 at the center region in the surface of the tandem-type solar cell module 100 and having a high crystallinity, but the second region 32 having a lower crystallinity than the first region 30.

Light entering from the transparent insulating substrate 10 passes through the slit S4 for separating the backside electrode 16 to the backside, but in the region where the tab electrode 22 is formed, the light transmitting through the slit S4 is reflected by the tab electrode 22 to the side of the photovoltaic unit 14. In the present embodiment, because the tab electrode 22 is formed in the second region 32 which is at a module peripheral region in which the microcrystalline silicon film of the i-type layer having a low crystallinity is formed, the light transmitting through the slit S4 is reused, an amount of generation of current near the region where the tab electrode 22 is formed is increased, and the balance with the amount of generation of the current in the first region 30 which is the center region of the module is improved. With this configuration, more uniform photoelectric conversion efficiency of the photoelectric conversion layer of the tandem-type solar cell module 100 as a whole can be achieved.

### Second Preferred Embodiment

In the tandem-type cell module 100 described above in the first preferred embodiment, it is preferable that, in the i-type layer of the microcrystalline silicon of the photovoltaic unit 14 (i-type layer of the μc-Si unit), a lifetime of a carrier in the first region 30 is lower than a lifetime of a carrier in the second region 32.

When the lifetime of the carrier in the first region 30 is assumed to be 1, the lifetime of the carrier in the second region 32 is preferably greater than or equal to 1.05. The lifetime of the carrier is measured using Microwave Photo Conductivity Decay (p-PCD) after a microcrystalline silicon film is formed to a thickness of 600 nm over a glass substrate under the same film formation conditions as the conditions for forming the i-type layer of the tandem-type solar cell module 100. More specifically, a method described in “Detection of Heavy Metal Contamination in Semiconductor Processes using a Carrier Lifetime Measurement System” (Kobe Steel Engineering Reports, Vol. 52, No. 2, September, 2002, pp. 87 - 93) is applied. In the μ-PCD, light is instantaneously irradiated in the regions in the surface of the microcrystalline silicon film formed over the glass substrate, and decay of the carrier due to the recombination occurring in the film by the light is measured as a change of reflection intensity of a microwave light which is separately irradiated on the microcrystalline silicon film.

The i-type layer of the μc-Si unit can be formed by employing different states of the plasma of the material gas for the first region 30 and the second region 32 during the film formation. In a first method, film is formed in a state where the potentials of the regions of the transparent conductive film 12 patterned in the strip shape by the slit S1 are set different from each other. For example, plasma CVD is applied while the transparent conductive film 12 corresponding to the first region 30 is set in a floating state and the transparent conductive film 12 corresponding to the second region 32 is grounded, to obtain the in-surface distribution of the i-type layer.

In a second method, different shapes may be employed for the plasma electrode corresponding to the first region 30 and the second region 32, to adjust the state of the generated plasma of the material gas within the surface. In a third method, different shapes, sizes, numbers, etc. may be employed for the gas shower holes formed in the plasma electrode corresponding to the first region 30 and the second region 32, to adjust the state of the generated plasma of the material gas.

FIG. 6 shows an example measurement of the distribution of the lifetime of the carrier in the surface of the i-type layer of the μc-Si unit of the tandem-type solar cell module 100 formed in the present embodiment. The lifetime of the carrier is measured by applying the μ-PCD after a microcrystalline silicon film is formed to a thickness of 600 nm over a glass substrate under the same film formation conditions as the conditions for forming the i-type layer of the tandem-type solar cell module 100. The measurement result of FIG. 6 shows the lifetimes in regions A-E of the tandem-type solar cell module 100 shown in FIG. 4. As shown in FIG. 6, when the lifetime of the first region 30 at the center of the surface (region C) is 1, the lifetime of the second region 32 at the periphery of the surface (regions A and E) is increased to approximately 1.14.

As described, in the present embodiment, in a surface of the tandem-type solar cell module 100, the first region 30 having a high crystallization percentage and a low lifetime of carrier, and the second region 32 having a lower crystallization percentage than the first region 30 and a high lifetime of carrier, are placed in the i-type layer of the μc-Si unit.

With this configuration, in a region where the crystallinity of the i-type layer is reduced due to the film formation conditions, such as the periphery of the substrate, the lifetime of the carrier can be increased, and in a region where the crystallinity is higher than such a region, the lifetime of the carrier can be shortened. As a result, more uniform photoelectric conversion efficiency can be achieved in the surface of the tandem-type solar cell module 100. Such a characteristic is advantageous when the tandem-type solar cell module 100 is to be made into a module.

When a panel of the tandem-type solar cell module 100 is formed, even when moisture enters from the outside at the peripheral portion of the substrate, because the crystallinity of the i-type layer at the peripheral portion is low, possibility of detachment can be further reduced.

What is claimed is:

1. A solar cell module comprising:
a microcrystalline silicon film as a photovoltaic layer, wherein
the microcrystalline silicon film of the photovoltaic layer comprises a first region and a second region having a lower crystallization percentage than the first region in a surface of the solar cell module, and
a tab electrode to a terminal box of the solar cell module is placed in a manner to overlap the second region.

2. The solar cell module according to claim 1, wherein
the first region is a center region in a panel of the solar cell module, and
the second region is a peripheral region in the panel of the solar cell module.

3. The solar cell module according to claim 1, wherein
a lifetime of a carrier in the first region is lower than a lifetime of a carrier in the second region.

4. The solar cell module according to claim 2, wherein
a lifetime of a carrier in the first region is lower than a lifetime of a carrier in the second region.

5. A method of manufacturing a solar cell module, comprising:
forming a microcrystalline silicon film comprising a first region and a second region having a lower crystallization percentage than the first region in a surface of the solar cell module, and
forming a tab electrode to a terminal box of the solar cell module in a manner to overlap the second region.

6. The method of manufacturing a solar cell module according to claim 5, wherein
the first region is a center region in a panel of the solar cell module, and
the second region is a peripheral region in the panel of the solar cell module.

7. The method of manufacturing a solar cell module according to claim 5, wherein
a lifetime of a carrier in the first region is lower than a lifetime of a carrier in the second region.

8. The method of manufacturing a solar cell module according to claim 6, wherein
a lifetime of a carrier in the first region is lower than a lifetime of a carrier in the second region.
